(19) United States
(12) Patent Application Publication
(10) Pub. No.: US 2016/0347115 A1
(43) Pub. Date: Dec. 1, 2016

(54) ORNAMENT PIECE AND MANUFACTURE METHOD

(71) Applicants: SHENZHEN FUTAIHONG PRECISION INDUSTRY CO., LTD., Shenzhen (CN); FIH (HONG KONG) LIMITED, Kowloon (HK)

(72) Inventors: MEI-HUI NIU, Shenzhen (CN); YU-TSAI WANG, New Taipei (TW)

(21) Appl. No.: 14/811,505

(22) Filed: Jul. 28, 2015

(30) Foreign Application Priority Data
May 30, 2015 (CN) 201510286457.8

(51) Int. Cl. B44C 1/22; B44C 3/00; C23C 14/02; C23C 14/58; C23C 14/14

(52) U.S. Cl. CPC B44C 1/228; C23C 14/5873; C23C 14/5813; C23C 14/14; C23C 14/024; B44C 3/005

(57) ABSTRACT

An ornament piece includes a base, a middle layer formed on the base and a surface layer formed on the middle layer. The middle layer includes a priming layer and a metal layer, the priming layer includes a matted metal texture, the metal layer includes a bright metal texture, the middle layer defines at least one groove. The at least one groove extends to the metal layer, a portion of the priming layer aligned to the groove is visual from the surface layer. A manufacture method of the ornament piece is also provided.

### FIELD

The subject matter herein generally relates to an ornament piece and a manufacture method of the ornament piece.

### BACKGROUND

Appearances of electronic devices are more and more important nowadays. Ornament pieces of the electronic devices are usually made by stoving varnish process, with simplex color. The ornament pieces with multiple colors may need extra manufactured, printing process, laser marking process, bronzing or heat transfer process for example, which is complicated. Therefore, the ornament pieces with multiple colors and simple manufacture process still need to be improved in the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is a plan view of a first exemplary embodiment of an ornament piece.

FIG. 2 is cross-sectional view of the ornament piece of FIG. 1 along an II-II line.

FIG. 3 is a plan view of a second exemplary embodiment of an ornament piece.

FIG. 4 is cross-sectional view of the ornament piece of FIG. 3 along an IV-IV line.

FIG. 5 is a plan view of a third exemplary embodiment of an ornament piece.

FIG. 6 is cross-sectional view of the ornament piece of FIG. 5 along an VI-VI line.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

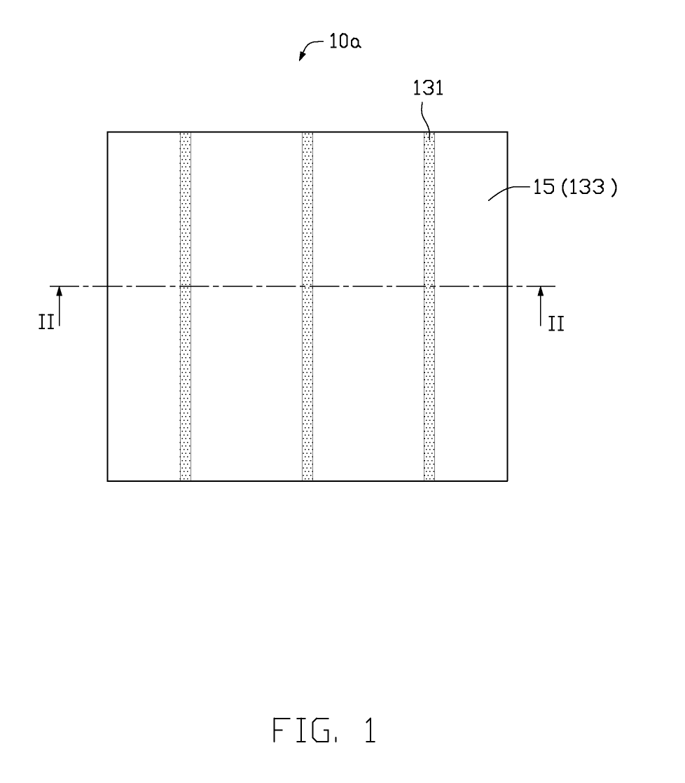

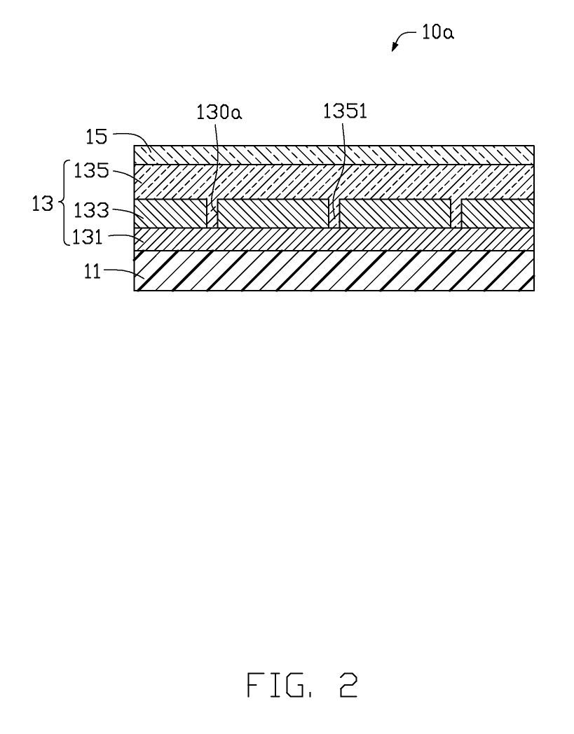

FIGS. 1 and 2 illustrate a first exemplary embodiment of an ornament piece 10a. The ornament piece 10a can be an appearance piece, a case for example, of an electronic device, such as a mobile phone, a personal digital assistant, or a tablet computer. The ornament piece 10a includes a base 11, a middle layer 13 and a surface layer 15. The middle layer 13 and the surface layer 15 are orderly formed on the base 11.

The base 11 can be made of plastic or a mixture material of plastic and fiberglass.

The middle layer 13 includes at least one layer having a color. In at least one embodiment, the middle layer 13 includes a priming layer 131, a metal layer 133, and a cladding layer 135.

The priming layer 131 is formed on at least one surface of the base 11. In at least one embodiment, the priming layer 131 is formed on one surface of the base 11. The priming layer 131 is made of stoving varnish material including metal granules. Thus, the priming layer 131 includes low brightness metal texture and the color, that is, the priming layer 131 includes matted metal texture. A thickness of the priming layer 131 is about 5-15 micrometer. Preferably, thicknesses of different portions of the priming layer 131 are no more than 2 micrometer.

The metal layer 133 is formed on a surface of the priming layer 131. The metal layer 133 is made of metal material and includes high brightness metal texture, that is, the metal layer 133 includes a bright metal texture. A thickness of the metal layer 133 is less than 500 nanometer. Thus, the metal layer 133 may not affect an antenna mounted inside the electronic device when the ornament piece 10 serves as the appearance piece of the electronic device. The metal layer 133 is formed by physical vapor deposition process.

The cladding layer 135 is formed on a surface of the metal layer 133. The cladding layer 135 is made of transparent or semitransparent material. Thus, the cladding layer 135 may not shield the metal texture of the metal layer 133 and the priming layer 131. The cladding layer 135 may include a color different from that of the priming layer 131.

The middle layer 13 further includes at least one groove 130a. A position, shape, and depth of the groove 130 can be adjusted accordingly. In at least one embodiment, the groove 130 is throughout defined the metal layer 133, thus to connect the priming layer 131 and the cladding layer 135. The cladding layer 135 further includes at least one inset portion 1351 received in the at least one groove 130a, thus to seamlessly attach the cladding layer 135 to the metal layer 133. Therefore, the priming layer 131 can be seen via the cladding layer 135 received in the at least one groove 130a. The groove 130a can be an aperture, gap or hole. The groove 130a may form a predetermined pattern by arrangement of the aperture, gap or hole. In at least one embodiment, the groove 130a is a gap. Furthermore, the predetermined pattern can be formed by different colors of the metal layer 133 and the priming layer 131 and different shapes or sizes of the groove 130a. The groove 130a can be formed by laser graving. A width of the groove 130a is greater than 0.03 millimeter when the groove 130a is a gap; a diameter of the groove 130a is greater than 0.02 millimeter when the groove 130a is a hole.

The surface layer 15 is formed on a surface of the cladding layer 135. The surface layer 15 is made of transparent or semitransparent material, such as ultraviolet curing paint. Thus, portions of the priming layer 135 corresponding to the groove 130a, the metal layer 133 and the cladding layer 135 can be seen via the surface layer 15. Therefore, the priming layer 131 and the metal layer 133 present metal textures with different brightness when seen via the surface layer 15. When the groove 130a is a gap and the ornament piece 10a densely defines a plurality of grooves 130, the ornament piece 10a presents drawbench visual effect seen via the surface layer 15. Furthermore, the ornament piece 10a can present better visual effect by overlying colors for the cladding layer 135. In addition, the surface layer 15 can improve an adhesion between layers and an abrasion performance of the surface of the ornament piece 10a.

In other embodiments, when the pattern is located in portions that are easy for leveling, edges of the ornament piece 10a for example, a preferable thickness of the surface layer 15 is about 12-15 micrometer. When the pattern is located in portions that are different for leveling, a preferable thickness of the surface layer 15 is about 16-25 micrometer.

A manufacture method of the ornament piece 10 is described as follows:

Providing a base 11 made of plastic or a mixture material of plastic and fiberglass.

Forming a priming layer 131 on at least one surface of the base 11. In at least one embodiment, forming a laser sensitive paint layer on the surface of the base 11 by stoving varnish process, and then roasting the base 11 in a temperature range of about 80-90° C. for 30-60 minutes to solidify the priming layer 131. Material of the priming layer 131 includes metal granules that with low brightness metal texture and color. A thickness of the priming layer 131 is about 5-15 micrometer. Preferably, thicknesses of different portions of the priming layer 131 are no more than 2 micrometer.

Forming a metal layer 133 on a surface of the priming layer 131. In at least one embodiment, the metal layer 133 is formed by physical vapor deposition process.

Forming at least one groove 130a throughout the metal layer 133 to expose the priming layer 131. The groove 130a extends from a surface of the metal layer 133 opposite to the priming layer 131 to a surface facing the priming layer 131, thus to expose a portion of the priming layer 131 corresponding to the groove 130a from the metal layer 133. In at least one embodiment, forming the groove 130a throughout the metal layer 133 by laser graving. A laser device operating the laser graving process can be a red light laser device or a green light laser device according to a color of the paint layer. An operation frequency of the laser device can be 2-3 MHz and a wavelength can be 1064 nanometer or 532 nanometer. A width of the groove 130a can be greater that 0.03 millimeter. The portion of the priming layer 131 corresponding to the groove 130a and the portions of the metal layer 133 beyond the groove 130a cooperatively form at least one pattern.

Forming a cladding layer 135 on a surface of the metal layer 133. In at least one embodiment, forming a laser sensitive paint layer on the surface of the metal layer 133 by stoving varnish process, and then roasting the base 11 with the paint layer in a temperature range of about 80-90° C. for 30-60 minutes to solidify the cladding layer 135. Some material are filled to the at least one groove 130a to form at least one inset portion 1351. A thickness of the cladding layer 135 is about 5-10 micrometer. Preferably, thicknesses of different portions of the cladding layer 135 are no more than 2 micrometer. The cladding layer 135 is made of transparent or semitransparent material. The cladding layer 135 may include a color different from that of the priming layer 131.

Forming a surface layer 15 on a surface of the cladding layer 135. The surface layer 15 can be by plating, printing, or stoving varnish. The surface layer 15 can be ultraviolet curing paint that can improve an adhesion between layers and an abrasion performance of the surface of the ornament piece 10a.

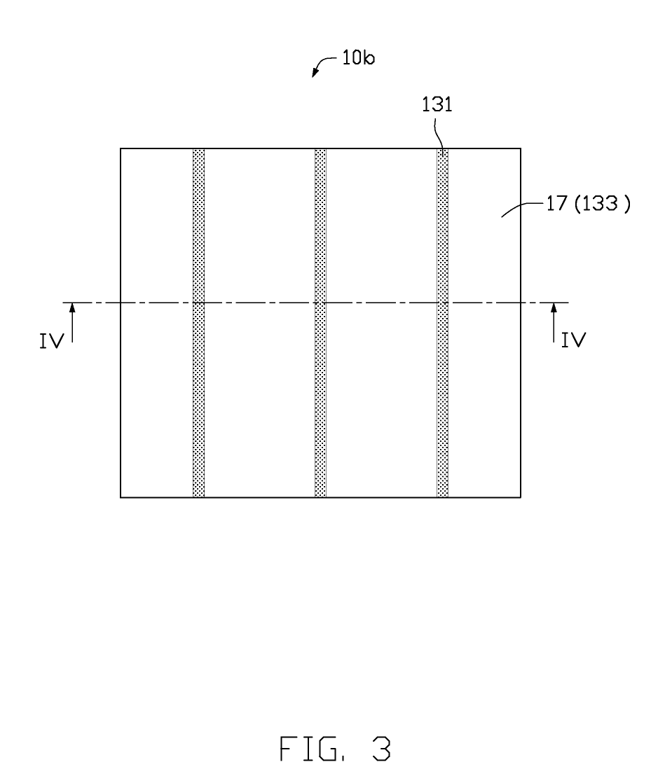

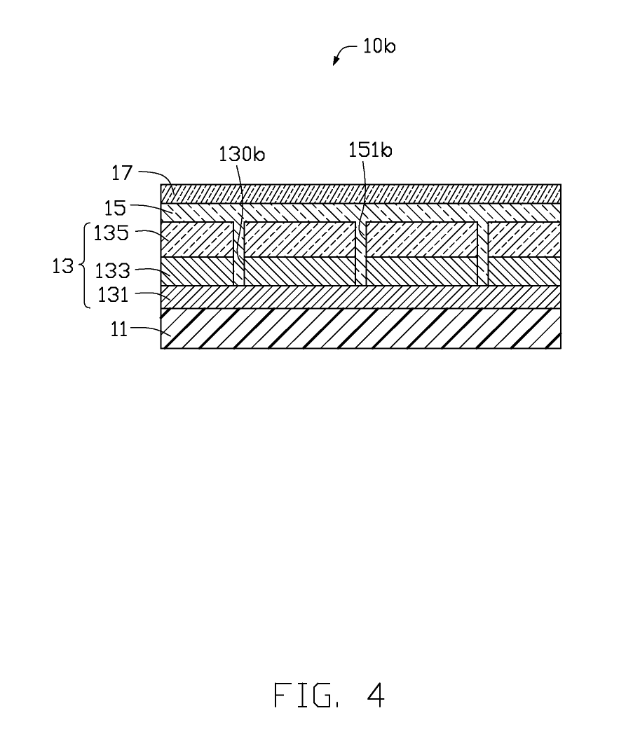

FIGS. 3 and 4 illustrate a second exemplary embodiment of an ornament piece 10b that similar to the ornament piece 10a of the first exemplary embodiment, with differences described as follows. Position of at least one groove 130b defined in the ornament piece 10b is different from that of the groove 130a in the ornament piece 10a. A protection layer 17 is formed on a surface of the surface layer 15. The groove 130b is defined throughout the cladding layer 135 and the metal layer 133, that is the groove 130b extends from a surface of the surface layer 15 facing the cladding layer 135 to a surface of the metal layer 133 facing the priming surface 131. The surface layer 15 includes at least one inset portion 151b correspondingly received in the at least one groove 130b. In other embodiments, a depth of the groove 130b can be adjusted according to different requirements, the groove 130b can extend from the surface of the cladding layer 135 facing the surface layer 15 to any layer of the middle layer 13, and the inset portion 151b can fill the groove 130b accordingly.

Differences of a manufacture method of the ornament piece 10b of the second exemplary embodiment with that of the ornament piece 10a of the first exemplary embodiment are described as follows. Forming at least one groove 130b throughout the clapping layer 135 and the metal layer 133. The groove 130b extends from a surface of the clapping layer 135 to a surface of the metal layer 133 facing the priming layer 131 to expose the color of the priming layer 131. In other embodiments, a depth of the groove 130b can be adjusted according to different requirements, the groove 130b can extend form a surface of the clapping layer 135 facing the surface layer 15 to any layer of the middle layer 13, and a depth of the inset portion 151b can also be adjusted according to the depth of the groove 130b. Forming a protection layer 17 on a surface of the surface layer 15 to improve a better manufacture of the ornament piece 10b. A material of the protection layer 17 can improve an adhesion between the protection layer 17 and the surface layer 15, for example, when the material of the protection layer 17 is ultraviolet curing paint, the material of the surface layer 15 can be ultraviolet curing paint or heat curing paint. In other embodiments, the process of forming the protection layer 17 can be ignored.

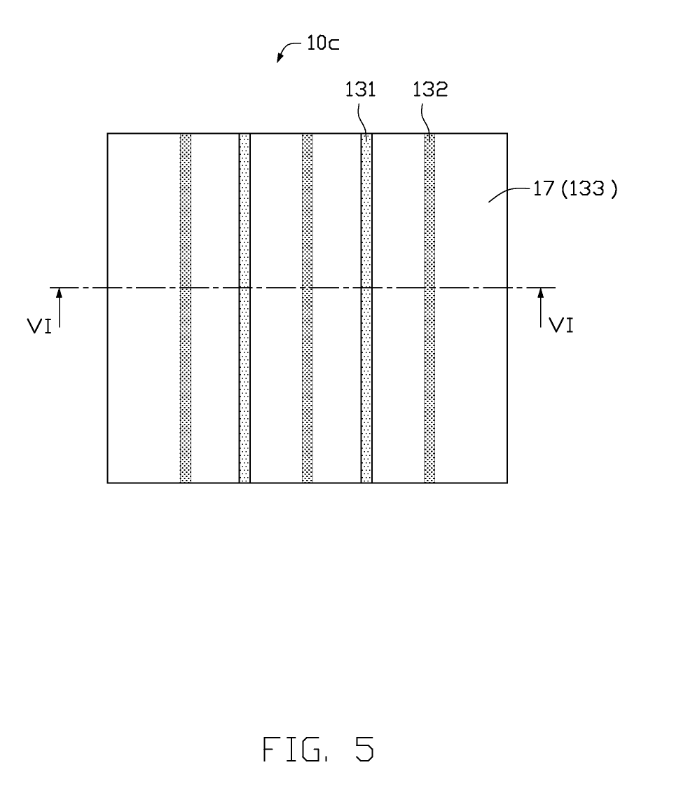

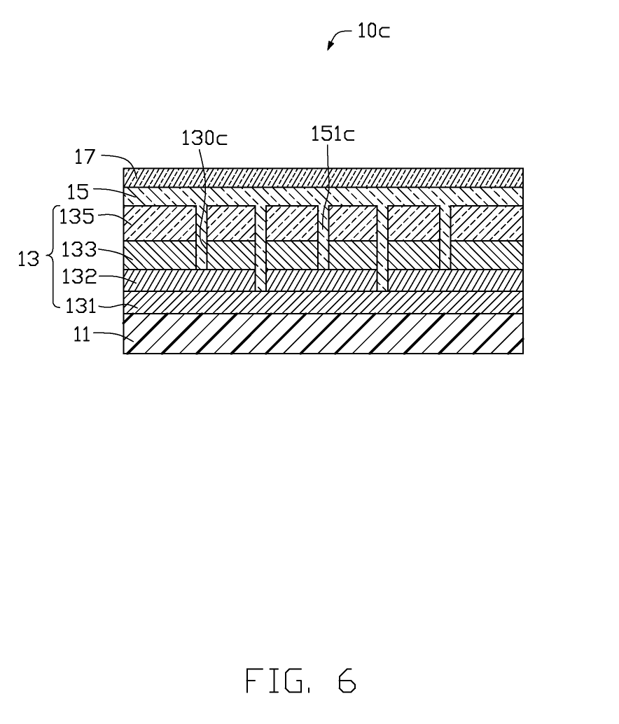

FIGS. 5 and 6 illustrate a third exemplary embodiment of an ornament piece 10c that similar to the ornament piece 10b of the second exemplary embodiment, with differences described as follows. The ornament piece 10c further includes a color layer 132 formed between the priming layer 131 and the metal layer 133. The middle layer 13 includes at least one groove 130c that a depth can be adjusted accordingly. In at least one embodiment, the middle layer 13 includes a plurality of grooves 130c, wherein a part of the grooves 130c extend from a surface of the cladding layer 135 opposite to the metal layer 133 to a surface of the metal layer 133 facing the color layer 132 to expose the color of the color layer 132; another part of the grooves 130c extend from a surface of the cladding layer 135 opposite to the metal layer 133 to a surface of the color layer 132 facing the priming layer 131 to expose the color of the priming layer 131. A surface layer 15 is formed on a surface of the cladding layer 135. The surface layer 15 defines a plurality of inset portions 151c to fill in the grooves 130c. The surface layer 15 can be made of transparent or semitransparent material, thus, viewing the ornament piece 10c via the surface layer 15, the ornament piece 10c can present three colors and metal texture effect.

Differences of a manufacture method of the ornament piece 10c of the third exemplary embodiment with that of the ornament piece 10b of the second exemplary embodiment are described as follows. Before forming the metal layer 133, forming a color layer 132 on a surface of the priming layer 131. In at least one embodiment, forming a laser sensitive paint layer on the surface of the priming layer 131 by stoving varnish process, and then roasting the base 11 with the paint layer in a temperature range of about 80-90° C. for 30-60 minutes to solidify the color layer 132. A thickness of the color layer 132 is about 5-10 micrometer. Preferably, thicknesses of different portions of the color layer 132 are no more than 2 micrometer. When a color of the priming layer 131 is darker, while a color of the color layer 132 is lighter, forming a render layer (not shown) with light color between the color layer 132 and the priming layer 131. Preferably, the color of the render layer can be argent, thus to avoid any affection to the color of the color layer 132 by the priming layer 131. A preferable thickness of the render layer is about 4-5 micrometer.

When the ornament piece needs to present more than three colors, the middle layer includes at least two paint layers with different colors which are different from the color of the base 11. The portions of the base 11 aligned to the grooves 130a/130b/130c are visual from the surface layer 15 by adjusting depths of the layers of the middle layer. Therefore, the ornament piece could present multiple colors.

The ornament piece 10a/10b/10c can present two or more than two colors by stoving varnish process and laser marking process. The colors are formed in different layers of the ornament piece, thus, the colors are hierarchy. The priming layer 131 and the metal layer 133 include metal texture with color, thus, the pattern formed on the ornament piece is more colorful and stereoscopic. A width of the groove is small, thus to achieve a matted and bright appearance effect and a drawbench effect. The manufacture method of the ornament piece is simple and costs less, which has advantage in marketing.

It is believed that the embodiments and their advantages will be understood from the foregoing description, and it will be apparent that various changes may be made thereto without departing from the scope of the disclosure or sacrificing all of its advantages, the examples hereinbefore described merely being illustrative embodiments of the disclosure.

What is claimed is:

1. An ornament piece comprising:
a base;
a middle layer formed on a surface of the base, the middle layer comprising a priming layer and a metal layer, the priming layer comprising a matted metal texture, the metal layer comprising a bright metal texture, the middle layer defining at least one groove; and
a surface layer formed on a surface of the middle layer;
wherein the at least one groove extends to the metal layer, and wherein a portion of the priming layer aligned to the groove is visual from the surface layer.

2. The ornament piece as claimed in claim 1, wherein the middle layer further comprises a cladding layer formed between the metal layer and the surface layer, the cladding layer comprises at least one inset portion to fill in the at least one groove.

3. The ornament piece as claimed in claim 2, wherein the middle layer further comprises a cladding layer formed between the metal layer and the surface layer, the at least one groove extends through the cladding layer, the surface layer forms at least one inset portion to fill in the at least one groove.

4. The ornament piece as claimed in claim 3, wherein the middle layer further comprises a color layer formed between the priming layer and the metal layer, a color of the color layer is different from that of the priming layer and the cladding layer; the middle layer defines a plurality of grooves, a part of the grooves extend through the cladding layer, the color layer, and the metal layer; another part of the grooves extend through the cladding layer and the color layer; the surface layer forms a plurality of inset portions to fill in the grooves.

5. The ornament piece as claimed in claim 2, wherein a thickness of the priming layer and the cladding layer is 5-15 micrometer, thicknesses of different portions of the priming layer and different portions of the cladding layer are no more than 2 micrometer.

6. The ornament piece as claimed in claim 2, wherein the cladding layer is made of transparent or semitransparent material, the cladding layer includes a color different from that of the priming layer.

7. The ornament piece as claimed in claim 1, wherein the base is made of plastic or a mixture material of plastic and fiberglass.

8. The ornament piece as claimed in claim 1, wherein the priming layer is made of stoving varnish material including metal granules.

9. The ornament piece as claimed in claim 1, wherein the metal layer is formed by physical vapor deposition process and has a thickness less than 500 nanometer.

10. The ornament piece as claimed in claim 1, further comprising a protection layer formed on a surface of the surface layer, wherein the a material of the protection layer is an ultraviolet curing paint configured to improve an adhesion between the protection layer and the surface layer.

11. A manufacture method of an ornament piece comprising:
providing a base;
forming a priming layer with matted metal texture on at least one surface of the base by stoving varnish process;
forming a metal layer with bright metal texture on a surface of the priming layer;
forming at least one groove through the metal layer by laser marking; and
forming a surface layer on a surface of the metal layer and filling the at least one groove with a material of the surface layer to form at least one inset portion, thus to finish manufacturing the ornament piece.

12. The manufacture method as claimed in claim 11, wherein after the laser marking process further comprising:
forming a cladding layer on a surface of the metal layer by stoving varnish process and filling the at least one groove with a material of the cladding layer, the cladding layer is made of transparent or semitransparent material and has a color different from that of the priming layer; and
forming a surface layer on a surface of the cladding layer with transparent or semitransparent material.

13. The manufacture method as claimed in claim 12, wherein the priming layer and the cladding layer are forming with laser sensitive paint and roasted in a temperature range of 80-90° C. for 30-60 minutes to be solidified.

14. The manufacture method as claimed in claim 11, wherein after the laser marking process further comprising:
forming a cladding layer on a surface of the metal layer by stoving varnish process, the cladding layer is made of transparent or semitransparent material and has a color different from that of the priming layer;
forming a plurality of grooves through the cladding layer and the metal layer by laser marking process to expose a color of the base; and
forming a surface layer on a surface of the cladding layer with transparent or semitransparent material.

15. The manufacture method as claimed in claim 11, further comprising:
forming a color layer between the priming layer and the metal layer with a color different from that of the priming layer and the metal layer.
